(19) United States
(12) Patent Application Publication
(10) Pub. No.: US 2007/0111547 A1
(43) Pub. Date: May 17, 2007

(54) Method for producing a semiconductor structure

(76) Inventors: Thomas Hecht, Dresden (DE); Stefan Jakschik, Kessel-Lo (Leuven) (BE); Christian Kapteyn, Dresden (DE)

Correspondence Address: JENKINS, WILSON, TAYLOR & HUNT, P. A., 3100 TOWER BLVD, SUITE 1200, DURHAM, NC, 27707, US

(21) Appl. No.: 11/582,656

(22) Filed: Oct. 18, 2006

(30) Foreign Application Priority Data
Oct. 28, 2005 (DE) 102005051819.2

(51) Int. Cl. H01L 21/31

(52) U.S. Cl. 438/791

(57) ABSTRACT

In a method for producing a semiconductor structure a substrate is provided, a dielectric layer comprising at least one metal oxide is formed on the substrate, and a nitrided layer is formed from the dielectric layer. The nitrided layer comprises either at least one metal nitride corresponding to the metal oxide or a metal oxynitride. The nitrided layer is removed selectively with respect to the dielectric layer in a predetermined etching medium.

### BACKGROUND OF THE INVENTION

The present invention relates to a process for producing a semiconductor structure.

Thin liner layers are very frequently used in the production of microelectronic devices. They are used either as dielectric or as interlayers.

### BRIEF SUMMARY OF THE INVENTION

A method for producing a semiconductor structure, comprises the steps of:
providing a substrate;
forming a dielectric layer of at least one metal oxide on the substrate;
forming a nitrided layer from the dielectric layer of at least one metal oxide, the nitrided layer including either at least one metal nitride corresponding to the metal oxide or a metal oxynitride; and
removing the corresponding nitrided layer selectively with respect to the dielectric layer in a predetermined etching medium.

The idea on which the present invention is based consists in completely or partially nitriding a layer of a metal oxide in a predetermined region, so that the etching properties of the nitrided region differ from the unnitrided region with respect to a predetermined etching medium. In other words, the nitrided region can be etched more easily using the predetermined etching medium than the unnitrided region, and can therefore be removed selectively with respect to the unnitrided region.

According to an embodiment of the inventive method, the dielectric layer is partially masked, and the corresponding nitrided layer is formed by converting the unmasked region of the dielectric layer in a nitrogen-containing atmosphere.

The corresponding nitrided layer may partially be masked by means of a mask, then the dielectric layer may be formed by converting the unmasked region of the corresponding nitrided layer in an oxygen-containing atmosphere, and then the mask may be removed.

The removal step may take place in SC12, phosphoric acid or hydrofluoric acid. The removal step in particular may take place in an aqueous solution, for example by immersion in the acids.

The metal oxide may be selected from the following group: Al₂O₃, HfO, TiO₂, Ta₃O₅, ZrO, ScO and rare earth oxides.

The metal nitride may be selected from the following group: AlN, HfN and SiN.

The metal oxynitride may be selected from the following group: Al—O—N, Hf—O—N, Ti—O—N, Ta—O—N, Zr—O—N, Sc—O—N, rare earth oxides.

The conversion may take place at a temperature between 700° C. and 1200° C., preferably in the range between 950° C. and 1050° C.

The production of the nitrided layer (nitriding) may be effected by a plasma process using nitrogen radicals.

According to one embodiment of the inventive method, the dielectric layer is provided as capacitor dielectric on the walls of a trench. Then, the trench is partially filled with a conducting filling as inner capacitor electrode, and then the dielectric layer above the top side of the conducting filling is converted into the corresponding nitrided layer in a nitrogen-containing atmosphere, the conducting filling serving as a mask for that part of the dielectric layer which is located below the top side of the conducting filling.

In another embodiment of the inventive method, the dielectric layer is provided as gate dielectric on the substrate. Then, a gate is provided and patterned on the dielectric layer, and then the dielectric layer next to the gate is converted into the corresponding nitrided layer in a nitrogen-containing atmosphere, the gate serving as a mask for that part of the dielectric layer which is located beneath the gate.

### BRIEF DESCRIPTION OF THE SEVERAL VIEWS OF THE DRAWINGS

Exemplary embodiments of the invention are illustrated in the drawings and explained in more detail in the following description. In the drawings:

FIG. 1A-C are diagrammatic illustrations of successive process stages of a process for producing a semiconductor structure as a first embodiment of the present invention,

FIG. 2A-F are diagrammatic illustrations of successive process stages in a process for producing a semiconductor structure.

FIG. 3A-C are diagrammatic illustrations of successive process stages in a process for producing a further semiconductor structure.

### DETAILED DESCRIPTION OF THE INVENTION

In the figures, identical reference designations denote identical or functionally equivalent components.

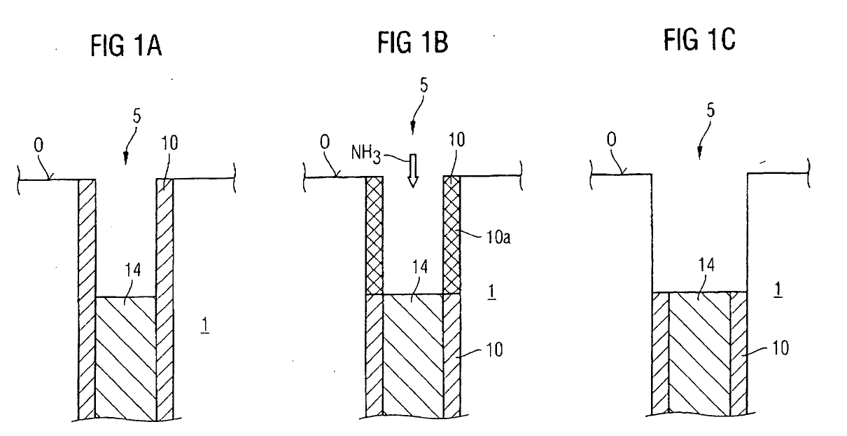

FIG. 1A-C show diagrammatic illustrations of successive process stages of a process for producing a semiconductor structure as a first embodiment of the present invention.

In FIG. 1, reference designation 1 denotes a silicon semiconductor substrate in which there is a trench 5, for example a deep trench for the capacitor of a semiconductor memory cell. A thin dielectric layer 10 of Al₂O₃, which in the case of the capacitor for a semiconductor memory cell represents the capacitor dielectric, is provided at the walls of the trench 5. Furthermore, a filling 14 of polysilicon, which in the case of the said capacitor for a memory cell forms the inner capacitor electrode, is provided in the interior of the trench 5. The filling 14 is recessed into the trench 5 with respect to the top side O of the semiconductor substrate 1.

Continuing with reference to FIG. 1B, a nitriding step then takes place in an NH₃ atmosphere at a temperature of approximately 900° C. In this nitriding step, the uncovered part of the layer 10 of Al₂O₃ is converted into a layer 10a of Al—O—N or Al—N, i.e. is nitrided. The dielectric layer 10a has different etching properties from the dielectric layer 10 with respect to certain etching media, such as for example SC12 (H₂SO₄/H₂O₂/NH₄OH), phosphoric acid, hydrofluoric acid. These etching media etch the dielectric layer 10a with a high selectivity compared to the dielectric layer 10 and also the substrate 1 and the filling 14, so that the dielectric layer 10a can be removed selectively with respect to the dielectric layer 10 and the substrate 1 and the filling 14 in the upper region of the trench, leading to the process state shown in FIG. 1C.

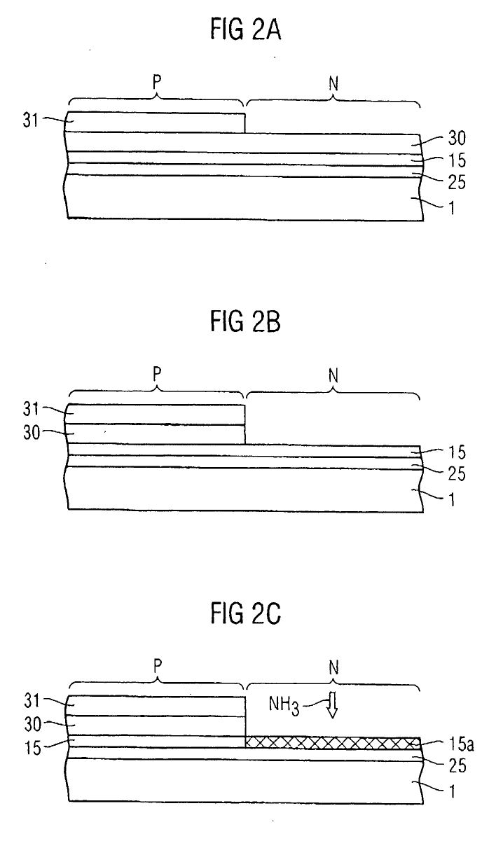

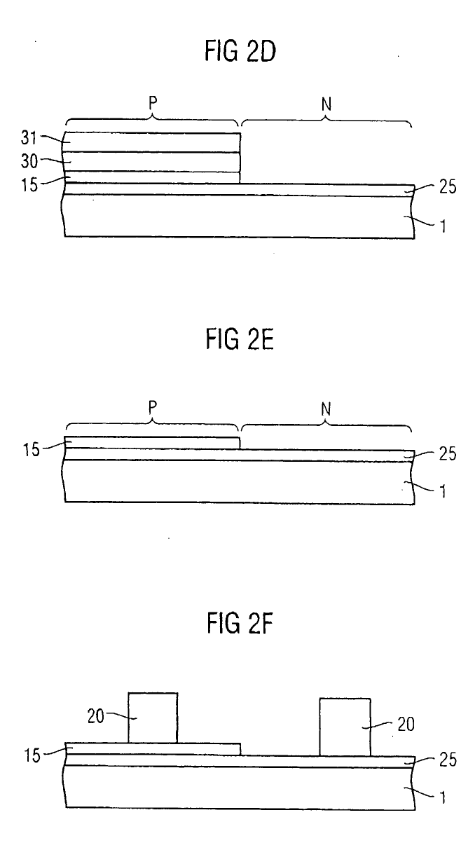

FIGS. 2A-E show diagrammatic illustrations of successive process stages of a process for producing a semiconductor structure as a second embodiment of the present invention.

In FIG. 2A, reference numeral 1 again denotes a silicon semiconductor substrate. A first dielectric layer 25, preferably a layer of SiO₂ or HfSiOₓ, has been applied to the semiconductor substrate 1, and a second dielectric layer 15 of a metal oxide, for example of Al₂O₃, has been applied to the first dielectric layer 25. A hard mask 30, for example of polysilicon or silicon oxide, has been deposited on the dielectric layers 15, 25. A photoresist 31 is arranged on the hard mask 30 and patterned in such a manner that a first region P is covered by the photoresist 31 and a second region N is uncovered. By way of example, PMOS transistors are to be produced in the first region P by subsequent patterning steps, and NMOS transistors are to be produced in the second region N.

A first patterning step provides for the pattern of the patterned photoresist layer 31 to be transferred into the hard mask 30 (FIG. 2B). This can be done by etching back the hard mask 30, in which case the Al₂O₃ layer 15 can be used as a stop layer.

Thereafter, the Al₂O₃ layer, which is now uncovered, can be exposed to an ammonia atmosphere NH₃ or another nitrogen-containing atmosphere. The nitrogen radicals convert the Al₂O₃ layer into an Al—N layer or an Al—O—N layer, i.e. nitrided layer 15a (FIG. 2C).

The nitrided layer 15a is then removed by a wet-etching step. The etching solutions listed in the first exemplary embodiment can be used for this step (FIG. 2D).

Finally, the photoresist 31 and the hard mask 30 are removed in the first region P. The removal of these masking layers can also take place in an appropriate way before one of the above-described steps. It is preferable for the photoresist layer 31 to be removed prior to the nitriding of the Al₂O₃ layer 15, since otherwise the layers 15, 25 could be contaminated by the photoresist layer 31. The result is the layer structure illustrated in FIG. 2E.

Gate stacks 20 are subsequently arranged in the region P and in the region N. Therefore, a dielectric layer of a metal oxide 15 and a silicon oxide layer 25 is provided for PMOS transistors in the region P. The NMOS transistors in the region N include only a gate dielectric layer comprising a simple silicon oxide layer 25 (FIG. 2F). The corresponding drain/source regions are not illustrated. The exemplary embodiment described therefore allows NMOS and PMOS with different dielectric layers to be processed in parallel.

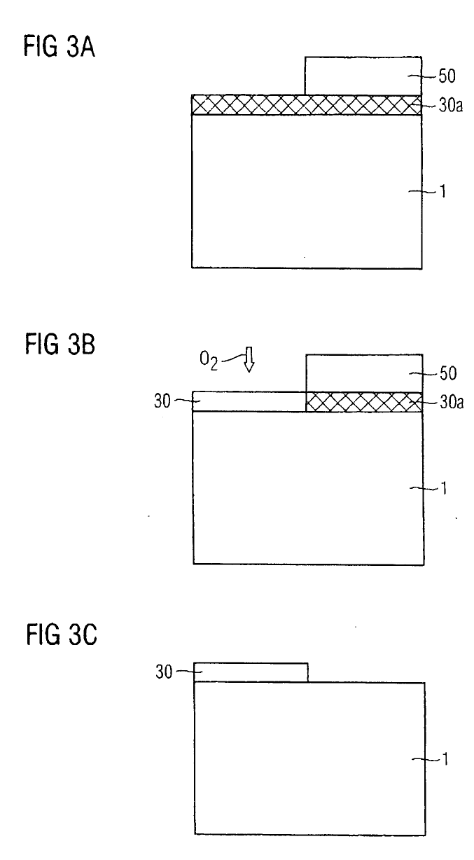

FIG. 3A-C show diagrammatic illustrations of successive process stages of a process for producing a semiconductor structure as a third embodiment of the present invention.

In the third embodiment shown in FIGS. 3A-C, reference numeral 1 likewise denotes a silicon semiconductor substrate. A nitrided liner layer 30A of Al—O—N or AlN has been applied to the semiconductor substrate 1. Also provided is a hard mask, for example of SiO₂, which masks part of the liner layer 30A as shown in FIG. 3A. Referring now to FIG. 3B, an oxidation step is carried out in an O₂ atmosphere at a temperature of 800° C., during which the uncovered part of the liner layer 30A is converted into a liner layer 30 of Al₂O₃. Then, the hard mask 50 is removed and a selective etch takes place in SC12, with the result that the nitrided liner layer 30A is removed selectively with respect to the liner layer 30.

Although the present invention has been described above on the basis of preferred exemplary embodiments, it is not restricted to these embodiments, but rather can be modified in numerous ways.

Although the above examples have cited Al₂O₃ as the dielectric layer, the present invention is not restricted to Al₂O₃, but rather can in principle be applied to all metal oxides which can be nitrided or to all corresponding metal nitrides which can be oxidized.

In addition to Al₂O₃, the oxides HfO, TiO₂, Ta₃O₅, ZrO, ScO, rare earth oxides, all metal and transition metal oxides and mixtures thereof appear to be particularly suitable.

Preferred nitrides are AlN, HfN, SiN and other nitrides of metals and transition metals and mixtures thereof. The same applies to oxynitrides.

Although in the above example an oxidation was carried out in O₂ atmosphere and a nitriding was carried out in NH₃, the present invention is not restricted to these particular details. It is also conceivable to use oxygen-containing or nitrogen-containing plasmas or NO-containing or O-containing gas mixtures.

The present invention can in principle be applied to all microelectronic regions, but a preferred application is for memory component technology with feature sizes of less than 70 nm.

What is claimed is:

1. A method for producing a semiconductor structure, comprising the steps of:
providing a substrate;
forming, on said substrate, a dielectric layer comprising at least one metal oxide;
forming a nitrided layer from said dielectric layer; said nitrided layer comprising either at least one metal nitride corresponding to said metal oxide or a metal oxynitride;
removing said nitrided layer selectively with respect to said dielectric layer in a predetermined etching medium.

2. The method of claim 1, further comprising masking partially said dielectric layer and forming said nitrided layer by converting an unmasked region of said dielectric layer in a nitrogen-containing atmosphere.

3. The method of claim 1, further comprising the steps of:
masking partially said nitrided layer by means of a mask;
forming said dielectric layer by converting an unmasked region of said nitrided layer in an oxygen-containing atmosphere; and
removing said mask.

4. The method of claim 1, wherein removing said nitrided layer is carried out in at least one of SC12, phosphoric acid, or hydrofluoric acid.

5. The method of claim 1, wherein said metal oxide is selected from the following group: Al₂O₃, HfO, TiO₂, Ta₃O₅, ZrO, ScO and rare earth oxides.

6. The method of claim 1, wherein said metal nitride is selected from the following group: AlN, HfN and SiN.

7. The method of claim 1, wherein said metal oxynitride is selected from the following group: Al—O—N, Hf—O—N, Ti—O—N, Ta—O—N, Zr—O—N, Sc—O—N and rare earth oxides.

8. The method of claim 2, wherein said converting takes place at a temperature between 700° C. and 1200° C.

9. The method of claim 2, wherein said converting takes place at a temperature between 950° C. and 1050° C.

10. The method of claim 1, wherein the step of forming said nitrided layer is effected by a plasma process utilizing nitrogen radicals.

11. The method of claim 1, comprising the steps of:
providing said dielectric layer as a capacitor dielectric on walls of a trench;
partially filling said trench with a conducting filling as an inner capacitor electrode; and
converting said dielectric layer above a top side of said conducting filling into said nitrided layer in a nitrogen-containing atmosphere; said conducting filling serving as a mask for a part of said dielectric layer which is located below said top side of said conducting filling.

12. The method of claim 1, comprising:
providing said dielectric layer as a gate dielectric on said substrate;
providing and patterning a gate on said dielectric layer; and
converting said dielectric layer next to said gate into said nitrided layer in a nitrogen-containing atmosphere; said gate serving as a mask for a part of said dielectric layer which is located beneath said gate.

13. The method of claim 1, comprising applying a further dielectric layer to said substrate prior to forming a metal oxide layer.

14. The method of claim 3, comprising forming PMOS transistors in a masked region and forming NMOS transistors in said unmasked region.
